(19) United States
(12) Patent Application Publication
(10) Pub. No.: US 2003/0071223 A1
(43) Pub. Date: Apr. 17, 2003

(54) Field ionizing elements and applications thereof

(76) Inventors: Frank T. Hartley, (US); Steven J. Smith, (US)

Correspondence Address: FISH & RICHARDSON, PC, 4350 LA JOLLA VILLAGE DRIVE, SUITE 500, SAN DIEGO, CA, 92122, US

(21) Appl. No.: 10/184,089

(22) Filed: Jun. 25, 2002

Related U.S. Application Data
(60) Provisional application No. 60/301,092, filed on Jun. 25, 2001.

(51) Int. Cl. H01J 37/08; H01J 49/16

(52) U.S. Cl. 250/423 F; 250/288; 250/287; 250/293

(57) ABSTRACT

A field ionizing element formed of a membrane that houses electrodes therein that are located closer to one another than the mean free path of the gas being ionized. The membrane includes a supporting portion, and a non supporting portion where the ions are formed. The membrane may be used as the front end for a number of different applications including a mass spectrometer, a rotating field mass spectrometer, a thruster, an ion mobility element, or an electrochemical device such as a fuel cell.

### STATEMENT AS TO FEDERALLY-SPONSORED RESEARCH

The invention described herein was made in the performance of work under a NASA 7-1407 contract, and is subject to the provisions of Public Law 96-517 (U.S.C. 202) in which the contractor has elected to retain title.

### CROSS-REFERENCE TO RELATED APPLICATIONS

This application claims benefit of U.S. Provisional Application No. 60/301,092, filed Jun. 25, 2001.

### BACKGROUND

Many different applications are possible for ionization systems. For example, it is desirable to form a pumpless, low mass sampling system for a mass spectrometer.

Conventional mass spectrometers often use “hard” techniques of producing ion fragments, in which certain parts of the molecule are forcibly removed, to form the fragmented ion. For example, the fragments may be produced by ultraviolet, radioactive, and/or thermal electron ionization techniques. Some of these techniques, and specifically the thermal technique, may require a vacuum to enhance the life of the filament source.

Different systems which use ionization are known. A quadrupole and magnetic sector/time of flight system ionizes a sample to determine its content. These devices have limitations in both operation and size. Many devices of this type may operate over only a relatively small mass sampling range. These devices may also suffer from efficiency issues, that is the ions might not be efficiently formed.

Many of these systems also require a very high vacuum to avoid ion collisions during passage through the instrument. For example, the systems may require a vacuum of the level of such as 10⁻⁶ Torr. A vacuum pump must be provided to maintain this vacuum. The vacuum pump consumes power, may be heavy, and also requires a relatively leak free environment. This clashes with the usual desire to miniaturize the size of such a device.

Other applications could be desirable for ionization, if an ionization system were sufficiently small. However, the existing ionization systems have problems and difficulties in fabrication which has prevented them from being used in certain applications.

### SUMMARY

The present application describes a special ionization membrane, along with applications of this special ionization membrane that are facilitated by the membrane.

A first application uses the ionization membrane as part of a mass spectrometer.

Another application uses the ionization membrane for other applications. According to an aspect of this invention, the electrodes are formed closer than the mean free path of a specified gas, for example the gas being considered. This may ionize gas molecules in free space. Different applications of this soft ionization technique are described including using this system in a mass spectrometer system, such as a rotating field mass spectrometer. This may also be used in a time of flight system.

In an embodiment, a pumpless mass spectrometer is described which does not include a pump for either forming the vacuum or for driving the ions.

Another embodiment describes using this system for an electrochemical system. Another application describes using this system in propulsion.

### BRIEF DESCRIPTION OF THE DRAWINGS

These and other aspects will now be described in detail with reference to the accompanying drawings, wherein

FIG. 1 shows Paschen curves for various gases;

FIGS. 2A-2C show details of the special ionization membrane of the present system, with FIG. 2B showing a cross-section along the line 2B-2B in FIG. 2B and FIG. 2A showing a close-up detail of one of the holes in FIG. 2B;

FIG. 3 shows a block diagram of a solid-state rotating field mass spectrometer;

FIG. 4 shows a harmonic dipole field spectrometer;

FIG. 5 shows a low-pressure rotating field mass spectrometer used for solid-state applications;

FIG. 6 shows an ion mobility spectrometer;

FIG. 7 shows a solid-state ionization membrane being used in an electrochemical device;

FIG. 8 shows the ionization membrane being used as a propulsion system;

FIG. 9 shows this propulsion system in its housing with top and bottom accelerator grids; and

FIG. 10 shows an aperture to carry the gas into the ionization field.

### DETAILED DESCRIPTION

Gas may be ionized in a high electric field. Avalanche arcing may be produced by the gas ionization. It has been found by the present inventor, however, that when the “mean free path” between molecules is greater than electrode separation, only ionization occurs.

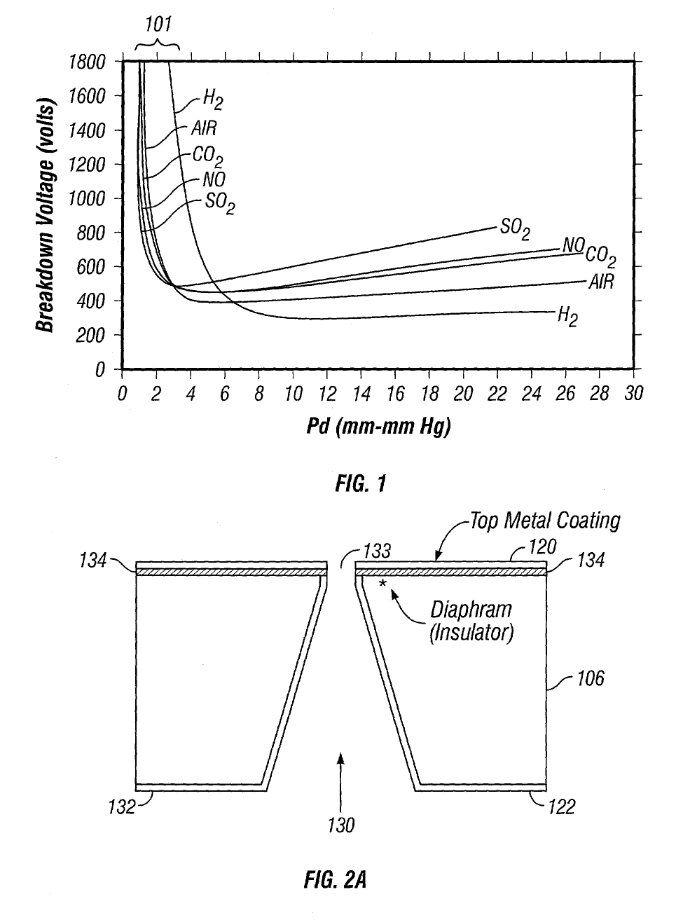

FIG. 1 shows the Paschen curves for various gases. This represents the breakdown voltage of the gas at various characteristic points. On the left side and under each Paschen curves. ionization of the gas occurs using the special membrane described herein. to This technique is “soft” in the sense that it ionizes without fragmenting the molecular structure of the gas being ionized. That means that large organic compounds can be analyzed without breaking them into smaller atomic fragments.

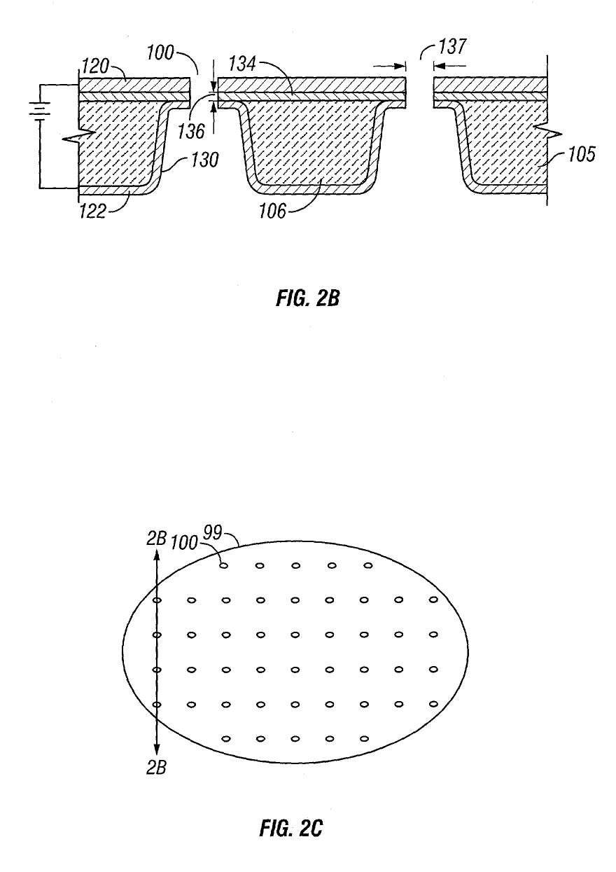

Details of the membrane are shown in FIGS. 2A 2C, with FIGS. 2A & 2B showing cross sections of the membrane of FIG. 2C. The miniature ionization device 99 is formed by micromachining an array of small holes 100 through a relatively thin membrane 105. The membrane 105 may be, for example, of sub micron thickness. The material 106 of the substrate itself may be silicon or any other easy-to-machine material. Metal electrodes 120,122 are located on respective sides of the membrane 100. The metal can be any material such as chrome or titanium or gold.

In formation of the membrane 99, a plurality of holes such as 130 are formed from the bottom 132. The holes may generally taper as shown towards the top portion 133 of the hole. The top portion 133 of the hole 130 may have a dimension 137 which may be, for example, 2 to 3 microns. Openings may be formed in the top metal coating 120, and in the bottom metal coating 122. For example, the hole may be formed by focused ion-beam milling (maskless process).

The substrate material 106 also includes a dielectric layer 134 which can be for example, silicon nitride, alumina, or any other similar material that has a similar dielectric breakdown. The thickness 136 of the dielectric layer sets the distance between the metal electrodes 120 and 122. The dielectric thickness can be to 200-300 nm The dielectric can in fact be thinner than 200 nm, in fact can be any thickness, with thicknesses of 50 nm being possible.

In a preferred system, the distance between the electrodes 120, 122 is less than 1 micron. When this small separation is maintained, electric field strengths on the range of mega volts per meter are produced for each volt of potential difference between the electrodes 120, 122.

The inventor has noted that the membranes could not be formed simply from the thin, sub micron elements. Membranes that are formed in this way could be too fragile to sustain a pressure difference across the membrane, or to survive a minor mechanical shock. In this embodiment, the thicker supporting substrate part 105 is used, and is back-etched through to the membrane. By forming the substrate in this way, that is with a relatively thick substrate portions such as 105/106, separated by back etched holes such as 100, the structure of the device can be maintained while keeping a relatively small distance between the electrodes.

An embodiment is described herein which uses the field ionizer array, which may be a micromachined field ionizer membrane, with a lateral accelerator, which is coupled to a rotating field mass spectrometer. In this embodiment, a self sampling or pumpless mass spectrometer may be used for ambient pressures <50 Torr without moving parts. Ultraviolet, radioactive ionization or thermal electrons sources are not required. Nor is a gas carrier feed system. In an embodiment, the spectrometer may obtain a large dynamic range, extending from singly charged gas ions to compound gases, to large DNA fragments which have sensitivities in the range of parts per billion.

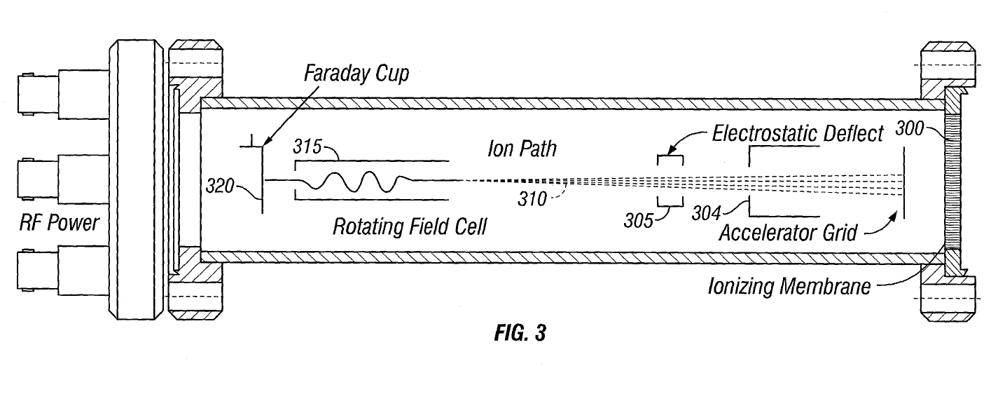

An embodiment using this solid state membrane in a mass spectrometer is shown in FIG. 3. An ionizing membrane 300 of the type previously described may be used. As described above, this membrane may include electrodes which are separated by a distance less than the mean free path of a material being ionized. The electrodes are applied with an energization from a voltage source, and the voltage source may provide an energy across the electrodes on the order of mega volts per meter.

The ions which are produced by the membrane 300 are then electrostatically deflected and focused by an accelerator grid 304 and other electrostatic parts 305, along an ion path 310.

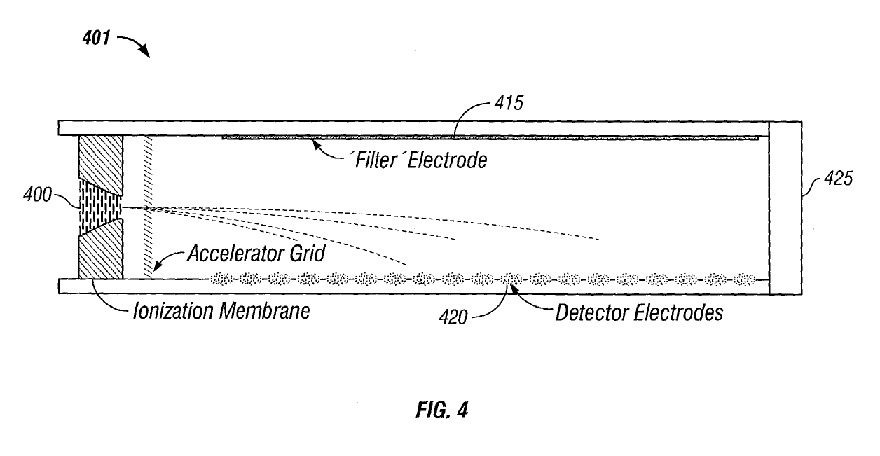

The focused ions on the ion path is launched into the cavity cell 315. For example, this may be a compact cell on the order of 2×2×20 mm. Within the cell 315, the frequency Q of the rotating electric field is varied, to scan through the desired range of ion masses. At each electric field value, the ions which have mass/charge that are in resonance with the current electric field value pass through the mass spectrometer according to a well-known helix geometry. The helix geometry is shown in further detail in FIG. 4. The ions that are in resonance land on the Faraday cup collector 320. Ions that are not in resonance strike other elements. Hence, the number of ions that strike the collector indicate the number of ions that are in resonance with the selected electric field value. By sweeping the field value across all possible levels, the content of the sample can be detected.

FIG. 4 shows details of how the helix geometry is related to information about the ion. The scanning frequency varies inversely with the mass of the ion. The detection of the striking of the Faraday cup detects the information about the ion.

In this system, the applied RF voltages may remain between 1 and 13 volts peak to peak, or more generally, less than 15 volts. Different detections may use different frequency ranges. For example, relatively lightweight gas molecules may be scanned at MHz frequencies. Larger organics, such as DNA organics, may be scanned at kHz frequencies. In general, lighter molecules may be scanned at higher frequencies. Importantly, this system can operate without any need for magnetic fields or for pumps. The system can operate at low pressure, and does not require a vacuum pump for the ions since electrostatic deflection is used to form the ion path. The control is dependent only on the applied RF field, as well as the partial pressure of the ion source.

An alternative mass spectrometer embodiment is shown in FIG. 5. This device uses an electronic image sensor to detect the position of impinging of the particles.

The material 500 is input through a filter, to an ionization membrane here 502, of the type previously described. The ionized particles then pass through an anode 505, through ion optics 510, and finally to the electrodes of a modified active pixel sensor array 520. The active pixel sensor array may be of the type described in U.S. Pat. No. 5,471,215, and as conventional may include various types of on-chip matrix processing. This system may use an electrode sensor of 1024 by 1024 pixels, with sub pixel centroiding and radial integration. The active pixel sensor itself may have a sensitivity on the order of 10-17 amps. By adding pixel current processing, another two orders of magnitude of sensitivity may be obtained.

This system may be used for sampling of the smallest possible ion masses (hydrogen having a mass of one atomic mass unit) to large fragments with masses greater than 10,000 AMU.

Forming the mass spectrometer in this way enables the device to be formed smaller, lighter, and with less cost than other devices of this type. This enables a whole range of applications; such as in situ biomedical sampling. One application is use of the miniature mass spectrometer is for a breathalyzer. Since there are no electron beam filaments and the like, any of the system components can operate at relatively higher pressures, for example 5 to 7 Torr pressures or higher. With a Faraday cup electrometer ion detector, sub femtoamp levels of sensitivity may be obtained. Moreover, the device can be made relatively small and low-power. For example a complete device may weigh 1 kg and consume 10 watts. A sub liter per second ion pump, or a membrane mechanical pump, can provide sufficient low pressure pumping. This system could be used as a portable device for finding various characteristics in exhaled breath. For example, detection of carbon monoxide in exhaled breath may be used as a screening diagnostic for diabetes.

Scanning can be carried out by sweeping frequencies between 0.4 MHz and 50 MHz. This would be sufficient to cover the entire mass range. Collisional processes will attenuate the ion beam as it travels through the system according to the attenuation expression I Attorney I₀exp^{(-nQtotL)} where n is the background gas number density, L the path length (20 mm), and Qₜₒₜ is the total cross section from all ion-into-neutral gas target collisional loss effects. These include elastic scattering, inelastic scattering from excitation and charge exchange processes small effects from Q_{elastic} is about 1×10⁻¹⁶ mm² and Q_{inelastic} for most species is about 10⁻¹⁵ mm². Hence a typical attenuation fraction is 0.0047. Since initial ion beams currents at the Faraday cup of 2×10⁻¹¹ Amp, currents may be readily measured with femtoamp resolving electrometers. In a closed system, where all incoming vapor passes through ionization membrane and is totally ionized, there will be fewer molecules traveling at thermal velocities and attention will be less.

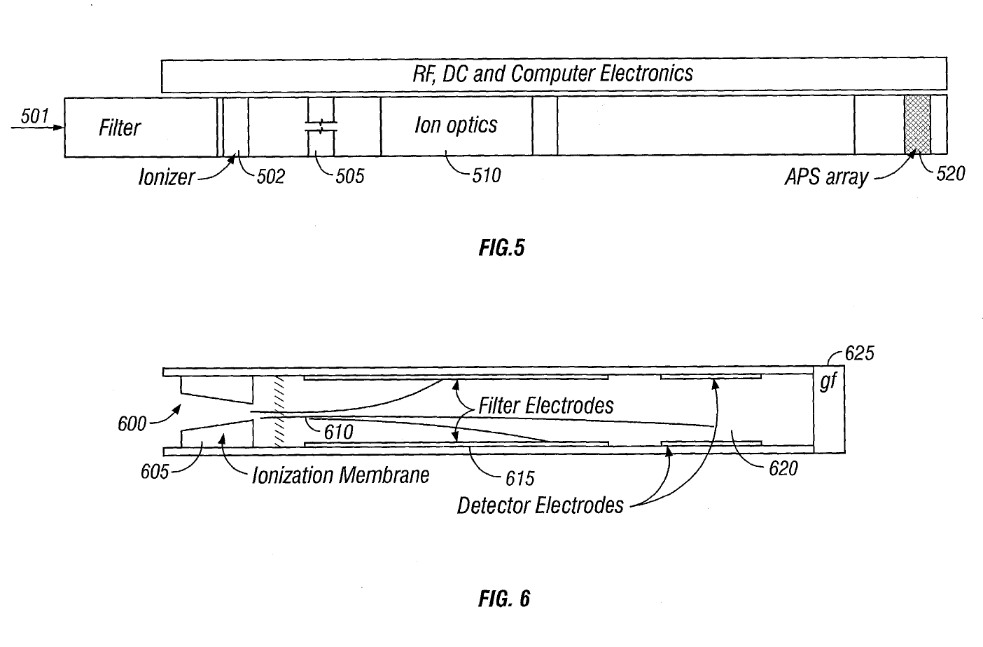

Another application of this system is for use in a miniature ion mobility spectrometer as shown in FIG. 6. Conventional ion mobility spectrometers use a shutter gate. This provides short pulses of ions. The shortened pulses of ions are often limited to about 1 percent of the total number of ions that are available for detection. However, resolution of such a device is related to the width of the ion pulse. The width of the ion pulse cannot be increased without correspondingly decreasing the resolution.

In the improved system of FIG. 6, total and continuous ionization of sample gas and continuous introduction of all ions into the chamber is enabled. Sample gases are introduced as 600 into the ionization membrane 605 of the type described above. In general, the ionization membrane 605 could include either a single pore device or could have multiple pores within the device.

Ions 610 from the membrane exit the membrane as an ion stream. Electrons in contrast move back behind (that is, to the others side of) the membrane, and may further contribute to the ionization of the incoming gases. The atoms or molecules are carried through the body of the spectrometer by a gas feed system 625. The gas feed system includes either an upstream carrier gas supply and Venturi sampler, or a downstream peristaltic pump.

The ions are drawn towards the filter electrode 615 which receive alternating and/or swept DC electric fields, for the transverse dispersal of the ions. A repetitive ramping of the DC fields sweeps through the spectrum of ion species.

An important feature of this device is the high field strengths which can be obtained. At moderate field strengths, for example <100,000 volts per meter, the mobility of ions at atmospheric and moderate pressures is constant. However, at higher field strengths, such as 2 million volts per meter or greater, the mobility of the ions is nonlinear. The mobility changes differentially for high and low mobility ions. This change may be, for example, by 20 percent. Therefore, by applying a waveform that is formed of a short high-voltage and a long low or negative voltage to the filter electrodes, the ion species is disbursed between the filter electrodes. This waveform may be selected to provide a zero time averaged field. In operation, the ions are transported laterally by a carrier gas stream. A low strength DC field may be supplied in opposition to the other field. This fields applied to the filter electrode may straighten the trajectory of specific ion species, allowing their passage through the filter. The other ion species collide with the electrodes. Sweeping of the DC field may facilitate detection of the complete ion spectrum.

Detector electrodes 620 are located downstream of the filter electrodes 615. The selected ions have straightened trajectories, and these detector electrodes 620 deflect the straightened-trajectory ions into detection electrodes, where they are detected. The detected current provides a direct measure of the number of ions. The number of ions is effectively proportional to the vapor concentration.

It should be understood that this gas feed system could be either upstream or downstream in this way.

Another embodiment uses this ionization technique to form a free space ion thruster.

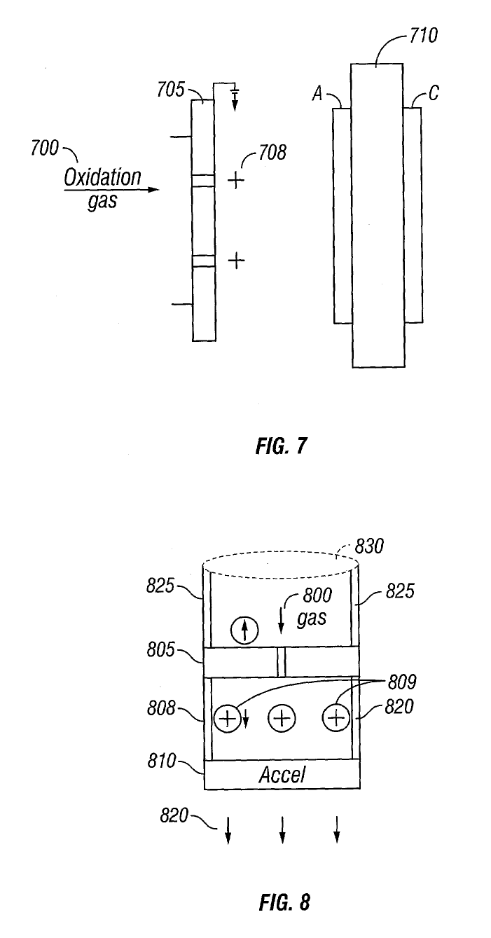

Yet another embodiment describes use of an ionizer of this type in a fuel cell. Previous fuel cell proton exchange membranes have used platinum or other electrooxidation catalysts to facilitate proton transfer. In this system, the oxidation gas or gases 700 is passed through the pores of a membrane 705 under an extreme electric field as shown in FIG. 7. The oxidation gas or gases 700 are completely ionized on passage through the membrane. The gas 708 once ionized, now has a positively charged aspect. The gas 708 drifts to the membrane 710 where the electrooxidized state of the gas enhances its transfer through the cathode. The transfer of atomic species through the membrane in this way reduces the partial pressure between the ionizer 705 and the membrane 710, this causing further inflow through the ionizer pores of the oxidation gas 702. The ionizer potential may alternatively be maintained positive with respect to the cathode membrane in order to accelerate the ions to an increased velocity before imprinting on the cathode membrane which forms the accelerator grid.

Another embodiment, shown in FIG. 8, uses this ionization membrane as part of a miniature ion thruster. This may form a thrust system using propellant gas. Propellant gas 800 is ionized by passing it through the pores of a membrane 805 of the type described above, under a high electric field. This forms positively charged ions 810 from the gas. The ions 809 enter another field 808 between the membrane and accelerator grid 810. This other field 808 accelerates the ions to an increased velocity, and expels them from the thruster as 820.

The electrons are caused to move back behind the membrane where a small electric field and magnetic field may linearly and rotationally accelerate the electron beam around to eject the electrons from the thruster with the same vector but reduced velocity as the ion beam. Since the ion and electron currents are substantially identical, this system becomes effectively charge neutral.

This system may use a small tube 820 of 1.5 cm long; 2 mm in diameter, of dielectric materials such as quartz. The tube 820 may be eutectically bonded to the top of the membrane 805. The micromachined conductive grid is similarly affixed to the top of the tube. The bottom of the membrane may also be eutecticly bonded to a thruster housing 825. That housing may contain another accelerating grid 830 and magnets.

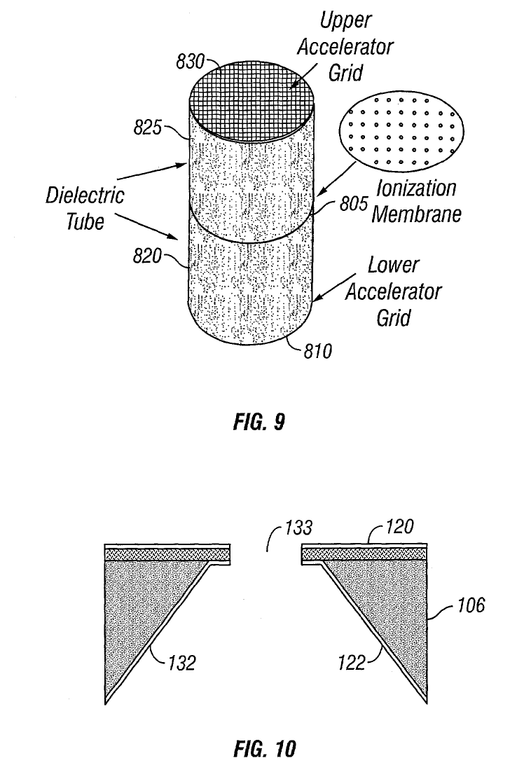

An exterior view of the structure is shown in FIG. 9, which shows the tube for any particular accelerator grid potential, the thrust of the engine is determined by the gas flow through the membrane pores. This system may use a plurality of miniature ionization tubes such as the one described above, that are disbursed across the surface of the structure. These tubes may be deployed individually or collectively by connecting them into a circuit. The ions from each of these tubes are accelerated under the influence of a localized electric field that is along the vector representing the least distance to the peripheral grid. The aggregate thrust is the geometrically integrated mass-momentum of all connected free space ion thrusters.

In this embodiment, a bipolar ion thruster may allow reversing the electrode potentials on the ionization membrane, causing the electrons to pass through the membrane, while ions move behind the membrane. The high velocity ions are expelled from the front of the thruster, and electrons are expelled from the rear of the thruster. This engine can therefore be reversed in this way.

When used in a vacuum, a low-pressure gas may need to be introduced into the membrane aperture that has a velocity sufficient to carry the gas into the ionization field. FIG. 10 shows an illustration of the way gas expands in a vacuum and has its molecules accelerated to supersonic speed while cooling, and directed through the membrane. Once ionized, the accelerating ions will create a partial vacuum behind them, which partial vacuum encourages further gas flow through the membrane. Gas that remains behind the membrane is ionized, and its negative field directs those ions through the membrane.

This system may have many different applications including biomedical applications such as a breath analyzer, as well as applications in other systems. It may have applications environment monitoring, personal monitoring, reviewing of water quality, automobile MAP control, detection of explosives, chemical and biological agent detection, and in an artificial nose type product.

What is claimed is:

1. A rotating field mass spectromemter system, comprising:
an ionizing device, comprising a substrate having at least one opening, a first conductive electrode extending on a first surface of the substrate and a second conductive electrode extending on a second surface of the substrate, and a separator insulating element, having a thickness less than 1 micron, separating said first and second conductive electrodes at said at least one opening, said first and second conductive electrodes being separated by a width of said insulator at said opening; and
a rotating field mass spectrometer part that receives ions from said ionizing device and which characterizes said ions.

2. A system as in claim 1, wherein said first and second conductive electrodes are separated by less than 300 nm at said at least one opening.

3. A system as in claim 1, wherein said separator insulating element is a dielectric.

4. A system as in claim 3, wherein said separator insulating element is formed of silicon nitride.

5. A system as in claim 1, wherein said first and second electrodes are formed of one of gold, chrome or titanium.

6. A system as in claim 1, wherein said mass spectrometer system operates at substantially ambient pressure.

7. A system as in claim 6, wherein said mass spectrometer system includes a solid-state electrode sensor array that detects ions.

8. A device as in claim 1, wherein there are plurality of said thin portions, and said thin portions each formed from first and second conductive electrodes which are separated by said less than 1 micron.

9. A device as in claim 1, wherein said first and second conductive electrodes are separated by less than a mean free path of a gas being analyzed.

10. A rotating field mass spectrometer system that operates without a vacuum pump.

11. A mass spectrometer system as in claim 10, further comprising a membrane which ionizes the material that passes therethrough, said membrane including electrodes which are separated by a distance less than a mean free path of the material being analyzed.

12. A mass spectrometer system as in claim 10, further comprising an electrostatic deflection element which forces ions along a path.

13. A mass spectrometer system as in claim 12, wherein said path includes a rotating field cell, which deflects the ions along a path of a specified helix shape.

14. A mass spectrometer system as in claim 11, further comprising an element which detects ions impinging in a specified location.

15. A mass spectrometer system as in claim 14, wherein said element includes a Faraday cup.

16. A mass spectrometer system as in claim 14, wherein said element includes a solid-state electrode array.

17. A rotating field mass spectrometer system, comprising:
an ionization membrane formed of a thick supporting portion with holes formed in the thick supporting portion and having first and second metal electrodes coated on surfaces of the thick supporting portion extending into the holes in the thick supporting portion, where a distance between the first and second metal electrodes within the holes of the thick supporting portion is less than the mean free path of a material being ionized; and
a rotating field mass spectrometer part, receiving ions formed by said ionization membrane.

18. A rotating field mass spectrometer system that operates without fragmenting an incoming sample.

19. A method of forming a rotating field mass spectrometer, comprising:
forming a layer of thin dielectric material on a substrate that has a first specified thickness of a sufficient thickness to maintain structural integrity;
forming a first electrode on the first surface of said thin dielectric material, said first electrode being formed of a metal material;
back etching at least one hole in said substrate;
forming a second electrode on a second surface of the substrate including the at least one back etching holes, such that at least a portion of the second electrode is on a second surface of the thin dielectric material;
forming holes in the second electrode, thin dielectric material and the first electrode, which holes have side surfaces where the first and second electrodes are separated by a width of the thin dielectric material; and
forming a rotating field mass spectrometer part to receive ions which have passed through said holes.

20. A method as in claim 19, wherein said thin dielectric material has a thickness which is less than the mean free path of the gas intended to be ionized by the ionization membrane.

21. A method as in claim 19, wherein said forming electrodes comprises depositing gold.

22. A method as in claim 21, wherein said forming a thin dielectric comprises depositing silicon nitride.

23. A method as in claim 19, wherein said thin dielectric has a thickness less than 500 nm.

24. A method as in claim 19, wherein said thin dielectric has a thickness less than 300 nm.

25. A method as in claim 24, further comprising applying a voltage less than 15 volts between said first and second electrodes to form a field between said first and second electrodes in the range of megavolts per meter.

26. A method as in claim 19, wherein said detecting comprises using a solid-state sensor to detect said ions.

27. A rotating field mass spectrometer, comprising:
an ionization membrane, having supporting portions, and unsupported parts between said supporting portions, where said unsupported parts include electrodes which are separated by a distance less than the mean free path of a specified sample, and include holes that pass through the ionization membrane; and
a rotating field mass spectrometer part, receiving ions from said ionization membrane, and determining characteristics of the ions.
